(19) United States
(12) Patent Application Publication
(10) Pub. No.: US 2008/0273565 A1
(43) Pub. Date: Nov. 6, 2008

(54) EXCITED STATE QUANTUM CASCADE PHOTON SOURCE

(76) Inventors: Claire F. Gmachl, Princeton, NJ (US); Kale J. Franz, Burlington, CO (US)

Correspondence Address: DANN, DORFMAN, HERRELL & SKILLMAN, 1601 MARKET STREET, SUITE 2400, PHILADELPHIA, PA, 19103-2307, US

(21) Appl. No.: 11/744,508

(22) Filed: May 4, 2007

(51) Int. Cl. H01S 5/34; H01L 33/00

(52) U.S. Cl. 372/45.012; 257/13; 257/E33.008

(57) ABSTRACT

A quantum cascade source, such as a QC laser, is provided comprising a plurality of repeat units each including an active region and an injector region. The active region includes at least two quantum wells that, in response to an applied electrical bias, provide a first, second, and third electron energy level, each resulting from a respective quantum well excited state. The first and second energy levels are configured so that an electron transition from the first energy level to the second energy level emits a photon of a selected wavelength. The second and third energy levels are configured so that an electron transition from the second energy level to the third energy level comprises a nonradiative transition to empty the second energy level sufficiently quickly to promote a population inversion between the first and second energy levels.

### GOVERNMENT LICENSE RIGHTS

Pursuant to 35 U.S.C. §202(c) it is acknowledged that the United States Government may have certain rights in the invention described herein, which was made in part with funds from the Defense Advanced Research Projects Agency, Grant Number (L-PAS) DE-AC05-76RL01830.

### FIELD OF THE INVENTION

The present invention relates generally to a quantum cascade (QC) photon source and more particularly, but not exclusively, to a quantum cascade laser that utilizes wide active region quantum wells to create a lasing transition between the excited states of the constituent wells.

### BACKGROUND OF THE INVENTION

Quantum cascade (QC) lasers have made possible the development of mid-infrared technologies—such as room temperature and compact trace gas sensing systems—that, before the QC laser's invention in 1994, were not feasible due to the lack of a high performing mid-infrared laser. See, for instance, J. Faist et al., Science, 264, 553-556 (1994) and C. Gmachl et al., Rep. Prog. Phys., 64, 1533-1601 (2001). This advance is due in part to the nature of the QC laser in which the optical transitions occur between electric subbands as contrasted to the conventional semiconductor laser in which optical transitions occur between the conduction and valence bands. To achieve this difference, the QC laser relies on a series of alternating thin layers of differing composition to create a cascade or series of energy steps that are built into the gain region. Thus, upon transmission through the QC gain region, electrons can emit a photon at each of the cascade steps, whereas for a diode laser one photon is emitted per electron transit through the gain region. Moreover, the ability to tailor the layer structure in the QC laser provides additional flexibility in wavelength design over the diode laser, since the QC laser wavelength dependence is not determined by the band gap of a single bulk material, as is the case with the conventional diode laser. However, despite these advantages and the added flexibility available in QC laser design, there exists in the field a need for improved QC lasers. For example, the accelerating flow of literature reporting advances in QC lasers strongly suggests optimality has yet to be reached. Thus, the need remains for QC lasers that exhibit improved performance, such as, for example exhibiting increased optical gain and requiring lower threshold currents.

### SUMMARY OF THE INVENTION

In one of its aspects, the present invention provides a quantum cascade source, such as a QC laser, comprising a plurality of repeat units each of which includes an active region and an injector region having a plurality of layers. The repeat units are stacked in contact with one another linearly along a direction perpendicular to the layers and are disposed between first and second electrical contacts for applying an electrical bias across the stacked repeat units. Each active region includes at least two quantum wells that, in response to an applied electrical bias, provide a first, second, and third electron energy level, with each energy level resulting from a respective quantum well excited state. The first and second energy levels are configured so that the first energy level is higher than the second energy level and so that an electron transition from the first energy level to the second energy level emits a photon of a selected wavelength. The second and third energy levels are configured so that the second energy level is higher than the third energy level and so that an electron transition between the second and third energy levels comprises a nonradiative transition to empty the second energy level sufficiently quickly to promote a population inversion between the first and second energy levels. Specifically, the energy difference between the second and third energy levels may be sufficient to emit an optical phonon.

In addition, the quantum cascade source may include a quantum well ground state energy level configured so that an electron transition from a selected excited state energy level to the ground state energy level emits a photon of a selected wavelength. In this regard, the photon emitted from the first to second energy level transition and the photon emitted from the second to ground state energy level transition may have the same or different wavelengths and may be correlated.

In another of its aspects, the present invention provides a quantum cascade source, such as a QC laser, comprising a plurality of repeat units each including an active region and an injector region having a plurality of layers. The repeat units are stacked in contact with one another linearly along a direction perpendicular to the layers and are disposed between first and second electrical contacts for applying an electrical bias across the stacked repeat units. Each active region includes at least two quantum wells that, in response to an applied electrical bias, support a first electron transition between a first pair of excited state energy levels to emit a photon of a first selected wavelength. Each active region also supports a second electron transition between a second pair of energy levels to emit a photon of a second selected wavelength. The lowest energy level of the first energy level pair and the highest energy level of the second energy level pair are separated in energy by an amount sufficient to emit an optical phonon. Specifically, the lowest energy level of the first energy level pair and the highest energy level of the second energy level pair may be separated in energy by at least that of two optical phonons. In addition, the second energy level pair may include two excited state energy levels or may include an excited state energy level and a ground state energy level.

In yet another of its aspects, the present invention provides a quantum cascade source, such as a QC laser, comprising a plurality of repeat units each including an active region and an injector region having a plurality of layers. The repeat units are stacked in contact with one another linearly along a direction perpendicular to the layers and are disposed between first and second electrical contacts for applying an electrical bias across the stacked repeat units. Each active region includes at least two quantum wells that, in response to an applied electrical bias, support only a single lasing electron transition between a pair of excited state energy levels to emit a photon of a selected wavelength. Each active region also supports a relatively lower energy level disposed below the lowest energy level of the energy level pair. The lowest energy level of the energy level pair and the relatively lower energy level are configured so that an electron transition therebetween comprises a nonradiative transition to empty the lowest energy level of the energy level pair sufficiently quickly to promote a population inversion between the energy levels of the energy level pair.

### BRIEF DESCRIPTION OF THE DRAWINGS

The foregoing summary and the following detailed description of the preferred embodiments of the present invention will be best understood when read in conjunction with the appended drawings, in which:

FIG. 1 schematically illustrates a conduction band diagram of a first exemplary embodiment of a QC laser in accordance with the present invention comprising a two-well active region that exhibits dual-wavelength emission from two consecutive optical transitions in each active region, one of which optical transitions occurs between two excited states;

FIG. 2A illustrates exemplary emission spectra of the QC laser of FIG. 1;

FIG. 2B illustrates exemplary electroluminescence spectra of a semi-circular mesa having a multilayer structure corresponding to that of the QC laser of FIG. 1;

FIG. 3 illustrates exemplary measured and calculated values of the optical transition energies in electroluminescence as a function of electric field;

FIG. 4 illustrates exemplary electroluminescence spectra along with theoretical calculations;

FIGS. 5A and 5B illustrate exemplary gated light versus current characteristics for emission wavelengths of 9.5 μm and 8.2 μm, respectively, of the QC laser of FIG. 1;

FIG. 6 schematically illustrates the calculated optical dipole matrix element of specified transitions as a function of well width for a given transition energy;

FIG. 7 schematically illustrates a conduction band diagram of a second exemplary embodiment of a QC laser in accordance with the present invention comprising a two-well active region that exhibits photon emission from a single optical transition in each active region that occurs between two excited states;

FIG. 8 schematically illustrates a conduction band diagram of a third exemplary embodiment of a QC laser in accordance with the present invention comprising a four-well active region that exhibits a double photon emission from two optical transitions each between two excited states;

FIGS. 9A and 9B schematically illustrate two quantum wells that are isolated from and coupled to one another, respectively, along with the associated moduli squared of exemplary wavefunctions; and

FIGS. 9C and 9D schematically illustrate two quantum wells of differing width that are isolated from and coupled to one another, respectively, along with the associated moduli squared of exemplary wavefunctions.

### DETAILED DESCRIPTION OF THE INVENTION

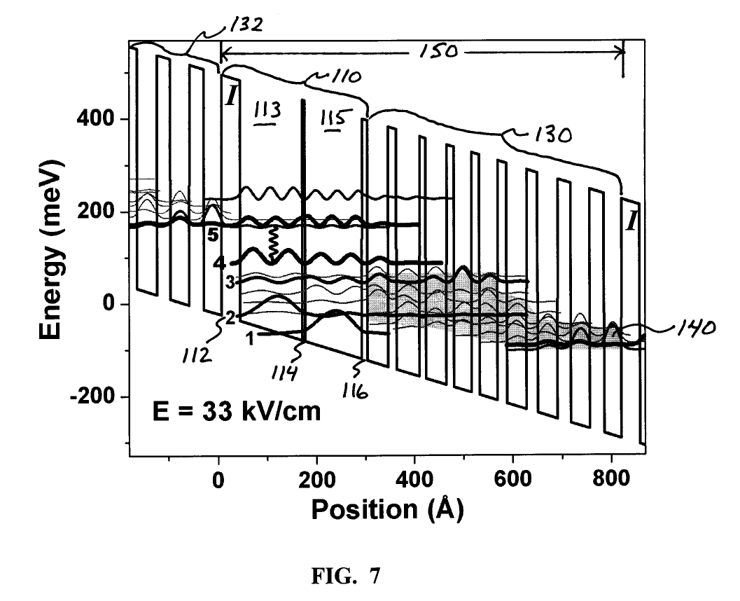

Turning first to FIG. 6, concepts common to the embodiments of the present invention described herein are shown illustrating certain advantages provided by QC photon sources, such as QC lasers, in accordance with the present invention. QC lasers of the present invention include at least two quantum wells and utilize at least one lasing transition between two excited states, e.g., the second- and first-excited states, of the constituent quantum well(s) of the active region. Such an excited state architecture comprising a lasing transition between two excited states has the potential for improving QC laser performance in at least two ways. First, the dipole matrix element between consecutive higher-level states is in general larger than between lower-level states, FIG. 6. Second, the wider active region wells that result from the excited state architecture of the present invention reduce the effects of scattering caused by interface roughness.

The gain coefficient g of a QC optical transition between an upper u and lower l state is given by

$$g = {τ}_{u} ( 1 - \frac{{τ}_{l}}{{τ}_{ul}} ) \frac{4 π e}{{ɛ}_{0} {n}_{eff} {λ}_{0} {L}_{p}} \frac{{z}_{ul}^{2}}{{Γ}_{ul}} \qquad ( 1 )$$

where τᵤ is the non-radiative scattering time of the upper state, τₗ the non-radiative scattering time of the lower state, and τᵤₗ the scattering time between the upper and lower state; e is the electron charge, n_{eff} the effective refractive index of the laser mode, λ₀ the free space wavelength, and Lₚ the length unit of gain of one period of active and injector region the QC structure; zᵤₗ is the optical dipole matrix element, and Γᵤₗ the full-width at half-maximum (FWHM) of the transition as measured from the luminescence spectrum.

As can be seen from Eq. (1), gain increases with the square of the optical dipole matrix element zᵤₗ. Therefore, steps that increase this value enhance the laser performance. FIG. 6 illustrates how the optical dipole matrix element evolves for the intersubband transitions between adjacent states for a single InGaAs/AlInAs:InP quantum well, which has a conduction band offset of 520 meV. The inset illustrates a quantum well with an energy difference of 125 meV between states 5 and 4. The moduli squared of states 1 through 5 are shown with the baseline corresponding to the energy of each state. Here, the optical dipole matrix element of a specific transition is calculated after adjusting the quantum well width to give a transition energy εᵤₗ of 125 meV. As can be seen, for the constant transition energy εᵤₗ=125 meV the optical dipole matrix element increases for higher lying transitions. Thus an optical transition between the second- and first-excited states of a quantum well will have a greater gain coefficient than a first-excited to ground state transition of equal energy. As used herein the terms first- and second-excited states, as well as those for higher order excited states, depart from one labeling convention commonly encountered in the field of QC lasers.

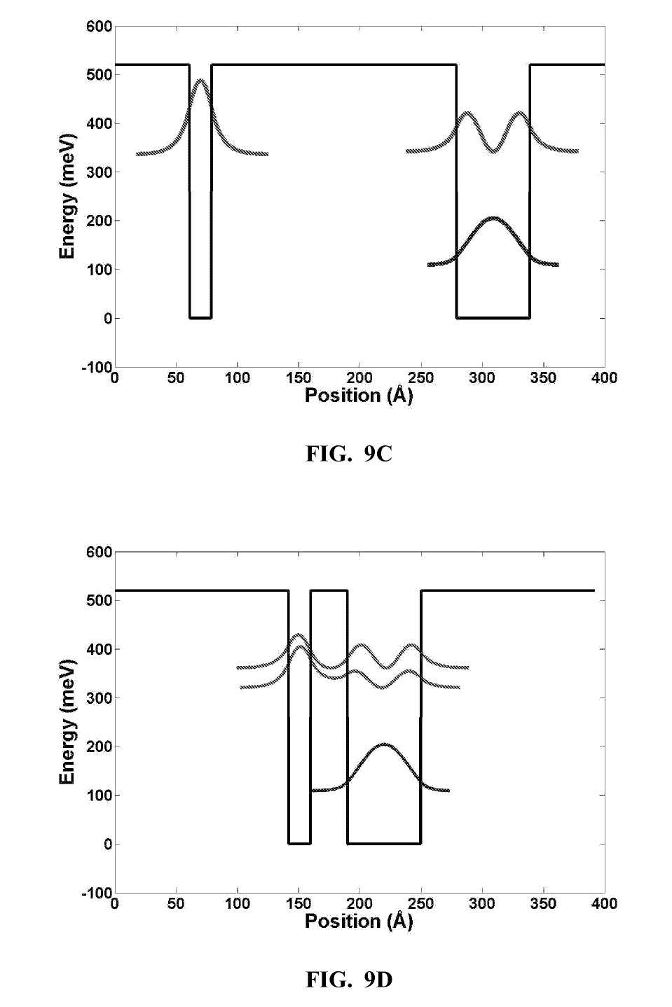

Specifically, while a standard convention is to label energy states in terms of the active region as a whole, whereby the active region state of lowest energy is the ground state, the state of next highest energy the first-excited state, and so on, an alternative convention is used herein, where each constituent quantum well of the active region is considered individually, instead of the active region as a whole, when labeling energy states. For example, referring to FIGS. 9A and 9B, given two isolated quantum wells 413, 415 of identical width that are not coupled (that is, a barrier 414 of sufficient size separates the two wells 413, 415 so that the respective energy states of the two wells 413, 415 remain substantially unaffected by each other), each well will have its own ground state 426, 427, first-excited state 428, 429, and so on, up to a the total number of states that are supported by the geometry and materials properties of the well and barrier regions. Should the barrier region 416 that isolates the two quantum wells 413, 415 be diminished (FIG. 9B), causing the energy states of the wells 413, 415 to substantially mix so that the two wells 413, 415 are considered coupled, the total number of energy states within the system of two wells 413, 415 will be substantially unchanged. Furthermore, each constituent quantum well 413, 415 of the two-well system will have its own respective ground state 436, 437 that will be “mixed” with the other well's respective ground state, similarly for the wells' first-excited states 438, 439, and so on. Thus, the system of two wells 413, 415 by the convention used herein has two “ground states” 436, 437 and two “first-excited states” 438, 439, whereas the standard convention would have only the state of lowest energy 437 labeled as the ground state, the state of next-highest energy 436 the first-excited state, and so on up to the third-excited state 438. In addition, the state labeling convention used herein takes into account the situation where a mixed state 548 of a constituent quantum well 513 results from the mixing of an excited state 529 of another quantum well 515 with the ground state 526 of constituent quantum well 513, in which case the resulting mixed state 548 is labeled an excited state of the constituent quantum well 513, FIGS. 9C, 9D. Moreover, the same analysis applies to the second lower-lying mixed state 549, also resulting from the mixing of the excited state 529 of the other quantum well 515 with the ground state 526 of the constituent quantum well 513, in which case the second lower-lying mixed state 549 would also be labeled an excited state under the convention used herein. In fact, since excited state 529 is a first-excited state, the resulting mixed states 548, 549 of quantum well 513 would both be labeled as first-excited states 548, 549 of quantum well 513. Accordingly, throughout this application including the claims, whenever the term “excited state” is used the term means an excited state as defined by the state labeling convention described above.

Returning now to FIG. 6, it should be noted that a tradeoff exists between the increase in the optical dipole matrix element from using higher excited states and the accompanying decrease in the magnitude of the population inversion—which is proportional to τᵤ(1−τₗ/τᵤₗ) in Eq. (1)—due to a decrease in upper state lifetime τᵤ. This upper state lifetime is decreased for the excited-state laser because of the larger number of lower empty levels into which electrons can scatter. Still, calculations confirm the effect of a larger optical dipole can dominate the effect of the decreased population inversion.

The second advantage of using an excited state optical transition, defined herein as an optical transition between two excited states of a constituent quantum well(s) of the active region, comes from the necessity of using wider wells, as shown in FIG. 6. Interface roughness at transitions between well and barrier material creates modifications of wavefunctions with respect to the ideal case of zero roughness at the interfaces. This surface roughness ultimately results in broadening of the emission spectrum Γᵤₗ, which reduces the gain coefficient g, as shown in Eq. (1). Interface roughness is a property of the growth quality and is usually on the order of one to two monolayers. Separate from improving the quality of the growth, the effects of interface roughness are reduced in wider wells, which intuitively can be motivated by the fact that the region of roughness is relatively smaller in wider wells. Due to the finite conduction band offset that may be used for quantum wells of the present invention, this excited-state architecture is especially suited for longer wavelength lasers where the second-excited state is more easily confined. Additionally, the invention should not be construed as only applicable to the materials system of the examples contained herein, that is, InGaAs/AlInAs lattice-matched to InP.

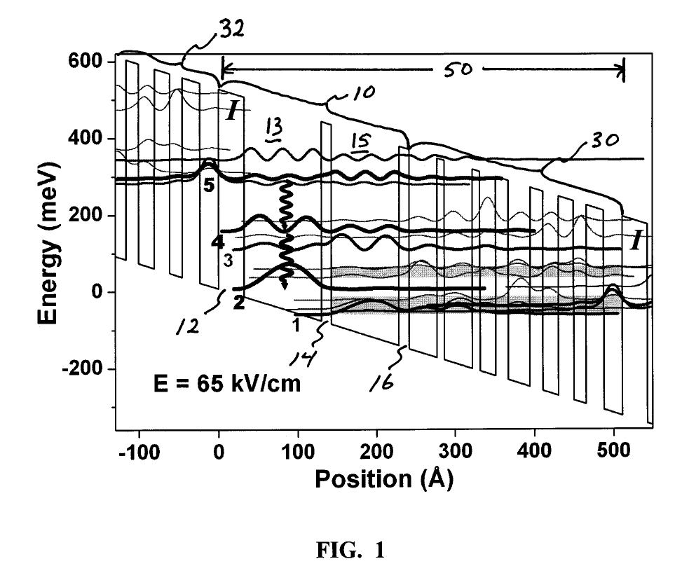

Turning now to FIG. 1, a conduction band diagram is schematically illustrated of a first exemplary embodiment of a QC laser in accordance with the present invention in which one full repeat unit 50, which comprises an active region 10 and an injector region 30, is shown along with a portion of the injector region 32 of the preceding upstream repeat unit. It is understood by one skilled in the art that the QC laser of the present invention includes a multiplicity of repeat units 50 stacked in contact with one another to provide the core region of the QC laser. Likewise, it is understood that the core may be disposed between cladding layers of a relatively lower refractive index than that of the core to provide an optical waveguide for enhanced confinement, and that electrical contacts are provided on opposing sides of the core so that a suitable electrical bias provided across the contacts can effect optical emission from the QC laser. Alternatively, in lieu of cladding layers, waveguide strategies such as the metal-metal waveguide are oftentimes advantageous for longer-wavelength emitters.

Considering FIG. 1 now in more detail, the active region 10 comprises first and second quantum wells 13, 15 disposed between three barrier layers 12, 14, 16, with the leading barrier layer 12 denoted conventionally as the injection barrier, “I”. The barrier layer 14 intermediate the two quantum wells 13, 15 is sufficiently thin to permit the quantum wells 13, 15 to be coupled. The active and injector region layer sequence of the repeat unit 50, as designed, is nominally (in angstroms, starting from the injection barrier I going from left to right in FIG. 1) 40/100/16/88/16/36/12/36/12/20/20/28*/20*/20*/24*/16/28/24, where In_{0.52}Al_{0.48}As barrier layers are in bold, In_{0.53}Ga_{0.47}As well layers are in normal text, and Si-doped 2×10¹⁷cm⁻³ layers are starred. Thus, the first and second quantum wells 13, 15 have a thickness of 100 Å and 88 Å, respectively, and the barrier layers 12, 14, 16 have a thickness of 40 Å, 16 Å, and 16 Å, respectively. The precise layer thicknesses illustrated in FIG. 1, however, are the thicknesses of a device that was fabricated in the manner detailed below, and due to fabrication parameters the layer thicknesses differ slightly from their design values.

A QC laser in accordance with the embodiment of FIG. 1 was grown with a Riber 32 gas-source molecular beam epitaxy (MBE) on a low-doped (n<2×10¹⁷ cm⁻³) InP:S substrate. Forty active region-injector periods were used for the active core, and were clad on top and bottom by 0.55 μm InGaAs (n=5×10¹⁶ cm⁻³) for enhanced confinement. A 0.9 μm InP (n=5×10¹⁶ cm⁻³) buffer layer was grown before the bottom InGaAs cladding. After the top InGaAs cladding, additional cladding layers of 3.9 μm InP (n=5×10¹⁶ cm⁻³) and 1.1 μm InP (n=6.7×10¹⁸cm⁻³) were grown, before capping the growth with 0.06 μm InGaAs (n=2×10¹⁹ cm⁻³). Following growth, the structure was post-calibrated by measuring active region and cladding layer thicknesses with scanning electron microscopy. It was found that the InAlAs growth rate was slow by 20%, which has been accounted for in the design and simulations, and which resulted in an active and injector region layer sequence of the repeat unit 50 of (in angstroms, starting from the injection barrier I going from left to right in FIG. 1) 32/98/13/86/13/35/10/35/10/20/16/27*/16*/20*/19*/16/23/23, where In_{0.52}Al_{0.48}As barrier layers are in bold, In_{0.53}Ga_{0.47}As well layers are in normal text, and Si-doped 2×10¹⁷cm⁻³ layers are starred. The as-grown band structure is shown in FIG. 1. The lasers were processed as deep-etched ridge waveguide lasers with stripe widths ranging from 9 to 15 μm by conventional photolithography and wet chemical etching, and were electrically insulated by 0.3 μm thick PECVD-deposited SiNₓ. After evaporation of a Ti/Au (30 nm/300 nm) top contact, the sample was thinned to ˜200 μm and a back Ge/Au (30 nm/300 nm) contact was evaporated. Laser bars were cleaved to 2.5 mm cavity length, mounted epilayer up on a Cu heat sink with In solder, and wire bonded.

The conduction band diagram of the as-grown structure also includes the moduli squared of the relevant wavefunctions showing cascaded optical transitions between levels 5→4 and 4→2, FIG. 1. Under the state labeling convention used herein, state 5 is a second excited state and is the upper energy state of the first optical transition. The lower energy state of the first optical transition (state 4) is a first-excited state. Thus, the 5→4 optical transition is an excited state optical transition. State 4 is also the upper state of the lower optical transition, making the two optical transitions “cascaded”, and state 2, the lower state of lower optical transition, is a ground state of the first quantum well 12. In addition, the energy difference between states 4 and 3 is sufficient to permit a nonradiative transition to empty state 4 sufficiently quickly to promote a population inversion between states 5 and 4. Moreover, the energy difference between states 4 and 3 may be sufficiently large to permit the emission of an optical phonon.

Simulation for the post-calibrated structure with a 65 kV/cm applied electric field results in an energy of 128.0 meV (λ=9.68 μm) for the upper optical transition (levels 5→4) and an optical dipole matrix element of z₅₄=31.0 Å; an energy of 151.5 meV (λ=8.18 μm) is calculated for the lower optical transition (4→2) and an optical dipole matrix element of z₄₂=14.4 Å. The waveguide loss is estimated at 7.4 cm⁻¹ for λ=9.68 μm and 5.1 cm⁻¹ for λ=8.18 μm. The optical confinement factor for the active core is 60% and 67% for the two wavelengths, respectively. Considering longitudinal optical (LO) phonon scattering as the only scattering process, lifetimes τᵢ of state i as τ₅=3.7 ps, τ₄=1.8 ps and τ₂=3.7 ps are calculated.

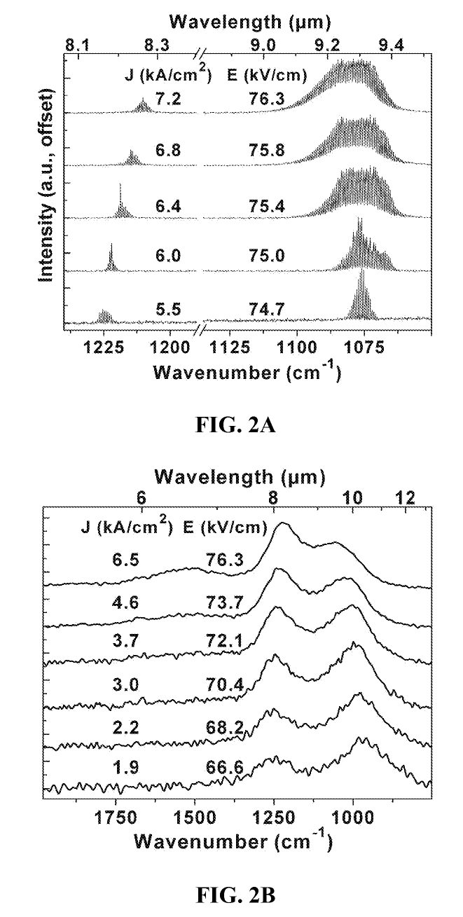

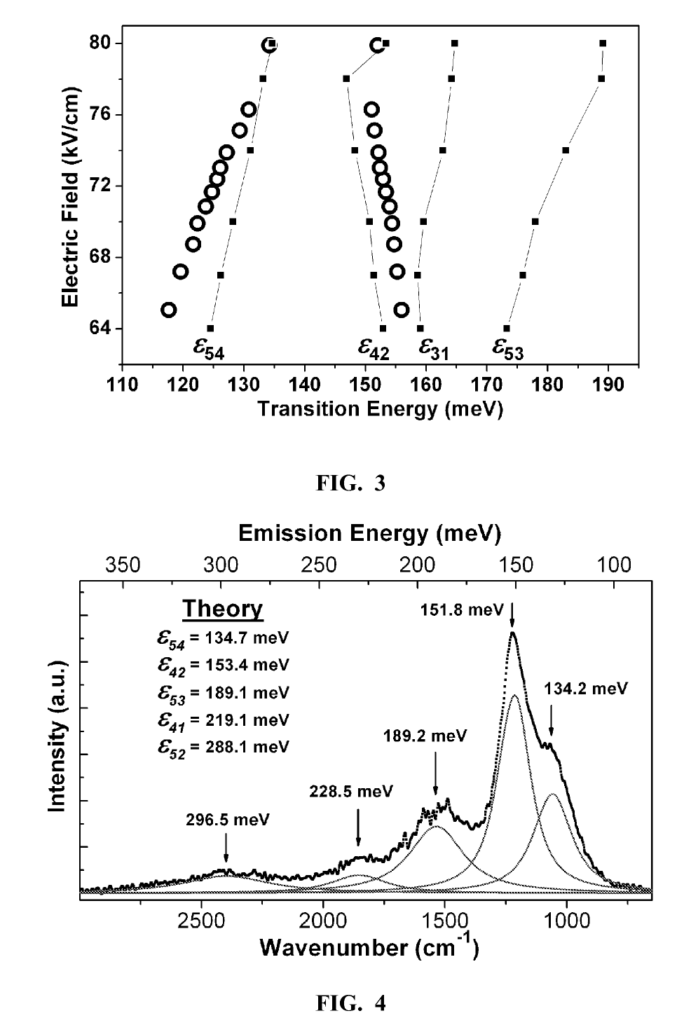

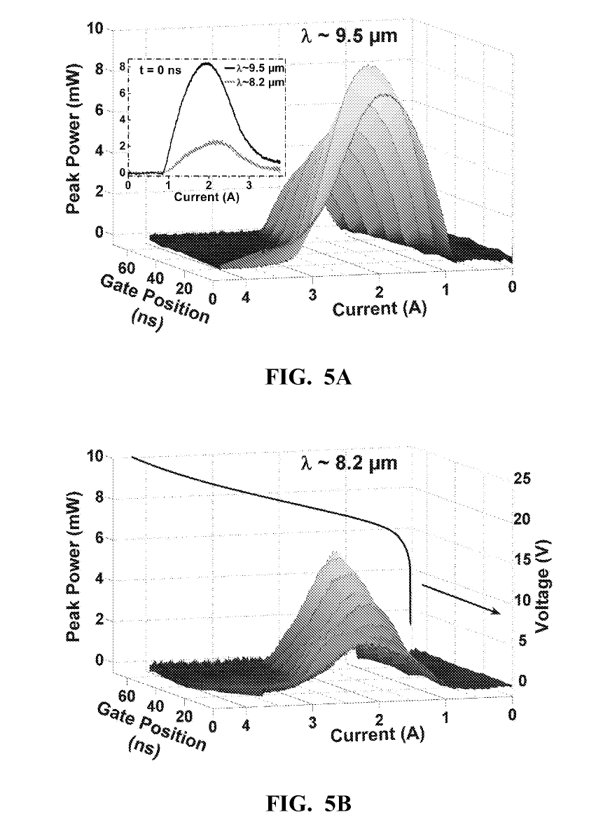

FIG. 2A shows time-integrated laser spectra collected using a Fourier Transform Infrared (FTIR) spectrometer. Spectra were taken using a current pulse width of 47 ns. The figure shows two distinct lasing peaks at λ˜9.3 μm and λ˜8.2 μm, in agreement with simulation for the transitions 5→4 and 4→2. The electric field across the active laser core is calculated from the current-voltage measurements. With increasing electric field, the spectral distance between the two lasing wavelengths narrows. Electroluminescence (EL) data exhibit similar characteristics. Deep, wet-etched, round mesas were patterned and processed, then cleaved into semi-circular structures to reduce optical feedback. The EL spectra—shown in FIG. 2B—exhibit two strong optical transitions that correspond to the two lasing wavelengths, and the peak centers show the same electric field tuning behavior as the laser devices. Fitting multiple Lorentzians for the 68 kV/cm spectrum gives a full-width at half-maximum (FWHM) of 18.7 meV for ˜9.5 μm light and 16.2 meV for ˜8.2 μm light. It was noted that state 5 extends over several interfaces, which can account for the broader 5→4 transition. Simulated electric field behavior of our structure is consistent with the observed data. The open circles in FIG. 3 represent multi-peak Lorentzian fits from EL data as in FIG. 2B. Squares depict simulated energies of four possible transitions. As expected, the ˜9.5 μm light results from transition 5→4. Because both the field behavior and energies of the 5→3 and 3→1 transitions differ from the EL and laser spectra, these two transitions were ruled out as the source of the ˜8.2 μm light. Thus it was determined that the transition 4→2 is the source of the ˜8.2 μm light. At a current of 2.5 A (80 kV/cm), five EL peaks are observed as shown in FIG. 4 with the center points indicated by arrows. Excellent agreement was found between observed and simulated data.

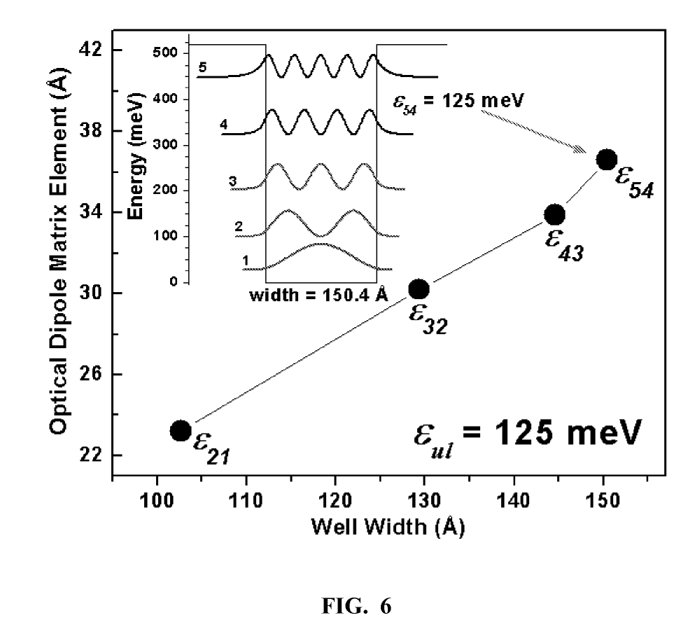

FIGS. 5A and 5B displays a series of spectrally-discriminate light-current-voltage (LIV) data where a boxcar gate is used to examine 14 ns portions of an 80 ns current pulse. At the leading edge of the current pulse, the two laser thresholds have similar magnitudes. As the current pulse progresses, the ˜8.2 μm light shows an increasing slope efficiency, and eventually overtakes the ˜9.5 μm light in power. Also, as the pulse progresses, the device must be pumped harder to turn on the ˜9.5 μm light, while the threshold for ˜8.2 μm light remains relatively constant throughout the pulse. The trend of less powerful ˜9.5 μm light relative to the ˜8.2 μm light is seen both with increasing pulse width (or gate position) and increasing temperature, suggesting the behavior is thermally induced. Phonon scattering is temperature dependent, with lifetimes decreasing as the temperature increases. While carriers are injected into state 5 by resonant tunneling, the population of state 4 is more thermally dependent since non-radiative phonon scattering contributes to the state 4 population. Thus level 4 populates more rapidly with increasing temperature, effectively reducing population inversion for the 5→4 transition while increasing inversion for the 4→2 transition.

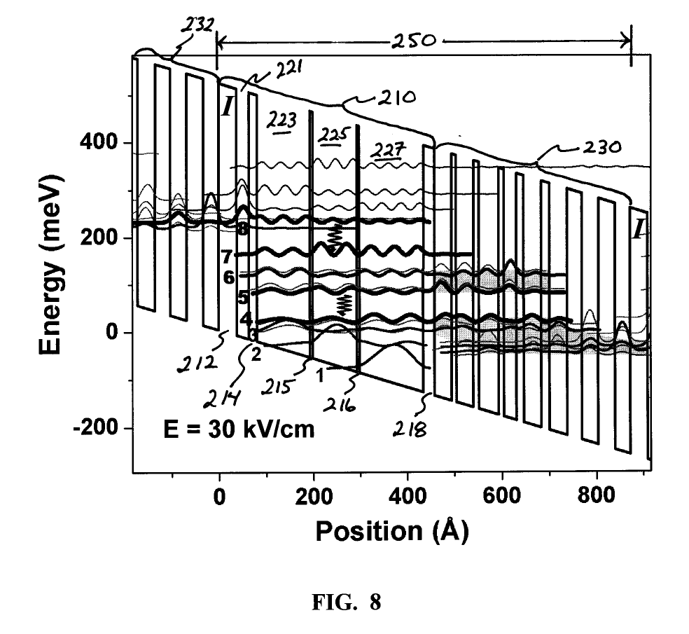

Turning next to FIG. 7, a conduction band diagram is schematically illustrated of a second exemplary embodiment of a QC laser in accordance with the present invention in which one full repeat unit 150, which comprises an active region 110 and an injector region 130, is shown along with a portion of the injector region 132 of the preceding upstream repeat unit. The active region 110 comprises a two-well structure disposed between three barrier layers 112, 114, 116, with the leading barrier layer 112 denoted conventionally as the injection barrier, “I”. The barrier layer 114 intermediate the two quantum wells 113, 115 is sufficiently thin to permit the quantum wells 113, 115 to be coupled. The active and injector region layer sequence of the repeat unit 150 is nominally (in angstroms, starting from the injection barrier I going to the right in FIG. 7) 38/126/6/116/12/42/17/47/13/42/15/36/16/36/19/40/23/40/27/3 8/30/35, where barrier layers are in bold and the well layers are in normal text. Thus, the first and second quantum wells 113, 115 have a thickness of 126 Å and 116 Å, respectively, and the barrier layers 112, 114, 116 have a thickness of 38 Å, 6 Å, and 12 Å, respectively. As will be appreciated with any of the design embodiments provided herein variations may be made by one skilled in the art, resulting in designs still within the scope of the instant invention. For instance, the active and injection region layer sequence may alternatively include the following sequence 43/126/6/116/12/42/17/47/13/42/15/36/16/36/19/40/23/40/32/40/40/36, which results in a device with about the same emission wavelength, but different transport characteristics.

The device of FIG. 7 is designed to have an optical transition between excited states 5 and 4 with emission energy that corresponds to 14.8 μm. Unlike the design of FIG. 1, the two quantum wells 113, 115 are more “balanced” for states 5 and 4, meaning that states 5 and 4 have approximately equal probability densities within each of the two active region wells 113, 115. This more balanced configuration typically increases the optical dipole matrix element, and thus increases the optical gain coefficient. Also, as a result of the lower-energy optical transition, the energy states of the optical transition lie lower in the active region quantum wells 113, 115, suppressing thermal excitation from state 5, and enhancing performance at elevated temperatures (that is, around room temperature).

A second difference between design of FIG. 7 and that of FIG. 1 is an improved injector region 130. Injector energy states are evenly distributed between state 3 of the active region 110 and state 5 of the next downstream active region, providing a continuum of states that act as a miniband 140 for rapid electron transport. The injector region 130 has an energy state positioned one LO phonon below state 3 (which extends significantly into the injector region 130), further facilitating the rapid transport of electrons between successive active regions.

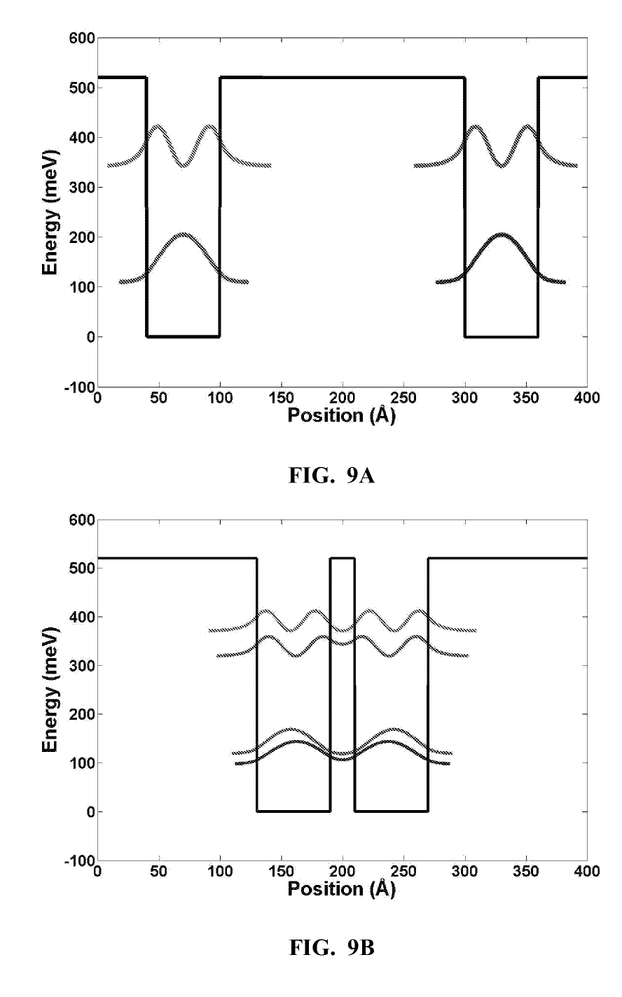

In addition to the above devices, a third exemplary embodiment of a QC laser in accordance with the present invention is schematically illustrated in FIG. 8. A conduction band diagram in which one full repeat unit 250, which comprises an active region 210 and an injector region 230, is illustrated along with a portion of the injector region 232 of the preceding upstream repeat unit. The active region 210 comprises a four-well structure disposed between five barrier layers 212, 214, 215, 216, 218 with the leading barrier layer 212 denoted conventionally as the injection barrier, “I”. The barrier layers 214,215, 216 intermediate the four quantum wells 221,223, 225,227 are sufficiently thin to permit the quantum wells 221, 223, 225, 227 to be coupled. The active and injector region layer sequence of the repeat unit 250 is nominally (in angstroms, starting from the injection barrier I going to the right in FIG. 8) 38/25/18/112/6/94/6/136/24/ 36/10/36/12/41/12/26/16/36/18/37/32/34/36/32, where barrier layers are in bold and the well layers are in normal text. Thus, the first through fourth quantum wells 221, 223, 225, 227 have a thickness of 25 Å, 112 Å, 94 Å, and 136 Å, respectively, and the barrier layers 212, 214, 215, 216, 218 have a thickness of 38 Å, 18 Å, 6 Å, 6 Å, and 24 Å, respectively.

As illustrated in FIG. 8, energy levels 8 and 7 provide the first excited state optical transition 262 which has a calculated energy separation of 65.5 meV. State 7 is rapidly de-populated by LO phonon scattering between 7 and 6. The energy difference between states 6 and 5 is also approximately that of an LO phonon, minimizing the electron lifetime between 6 and 5. State 5 is the upper energy level of the second excited state optical transition 264. The approximate two-LO-phonon energy difference between states 7 and 5 reduces any effect of thermal backfilling from state 5 into state 7, as compared to the case with a single LO phonon between the lower energy state of the first optical transition 262 (here, state 7) and the upper energy state of the second optical transition 264 (here, state 5). State 4 is the lower energy state of the second optical transition 264, and the calculated energy difference between states 5 and 4 is 59.0 meV. To promote population inversion between states 5 and 4, state 4 is depopulated by both LO phonon scattering to lower-lying states and electron tunneling out of the active region 210 into the injector region 230.

Notably, state 8 is a mixture of the first well 221 ground state, the second well 223 second-excited state, the third well 225 second-excited state, and forth well 227 third-excited state. States 7, 6, and 5 are mixtures of the second well 223 first-excited state, third well 225 first-excited state, and forth well 227 second-excited state. State 4 is a mixture of the second well 223 ground state, the third well 225 ground state, and the fourth well 227 first-excited state.

The injector region 230 is designed with “companion” energy states to active region states 6 and 5, followed by an energy gap before companion states to active region states 4 and 3. By placing two injector states higher in the quantum wells of the upstream portion of the injector region 230 and near the active region states 6 and 5, the effects of parasitic injector-region states that aid in thermal excitation from active region state 8 are reduced.

These and other advantages of the present invention will be apparent to those skilled in the art from the foregoing specification. Accordingly, it will be recognized by those skilled in the art that changes or modifications may be made to the above-described embodiments without departing from the broad inventive concepts of the invention. For instance, although the embodiments described above were directed to QC lasers, those skilled in the art understand that the layer architecture of the repeat units may be used for other QC photon sources, such as the QC counterparts to LEDs. It should therefore be understood that this invention is not limited to the particular embodiments described herein, but is intended to include all changes and modifications that are within the scope and spirit of the invention as set forth in the claims.

What is claimed is:

1. A quantum cascade source, comprising:
a plurality of repeat units each including an active region and an injector region having a plurality of layers, the repeat units stacked in contact with one another linearly along a direction perpendicular to the layers and disposed between first and second electrical contacts for applying an electrical bias across the stacked repeat units, each active region having at least two quantum wells that, in response to an applied electrical bias, provide a first, second, and third electron energy level, each energy level resulting from a respective quantum well excited state, the first and second energy levels configured so that the first energy level is higher than the second energy level and so that an electron transition from the first energy level to the second energy level emits a photon of a selected wavelength, and the second and third energy levels configured so that the second energy level is higher than the third energy level and so that an electron transition between the second and third energy levels comprises a nonradiative transition to empty the second energy level sufficiently quickly to promote a population inversion between the first and second energy levels.

2. The quantum cascade source according to claim 1, wherein the energy difference between the second and third energy levels is sufficient to emit an optical phonon.

3. The quantum cascade source according to claim 2, wherein the energy difference between the second and third energy levels corresponds to that of an optical phonon.

4. The quantum cascade source according to claim 1, comprising a quantum well ground state energy level configured so that an electron transition from a selected excited state energy level to the ground state energy level emits a photon of a selected wavelength.

5. The quantum cascade source according to claim 4, wherein the selected excited state energy level is the second energy level.

6. The quantum cascade source according to claim 5, wherein the photon emitted from the first to second energy level transition and the photon emitted from the second to ground state energy level transition are correlated.

7. The quantum cascade source according to claim 5, wherein the photon emitted from the first to second energy level transition and the photon emitted from the second to ground state energy level transition have the same wavelength.

8. The quantum cascade source according to claim 5, wherein the photon emitted from the first to second energy level transition and the photon emitted from the second to ground state energy level transition have different wavelengths.

9. The quantum cascade source according to claim 5, wherein the electron transition from the second to the ground state energy level is a vertical transition.

10. The quantum cascade source according to claim 1, wherein the electron transition from the first to the second energy level is a vertical transition.

11. The quantum cascade source according to claim 1, wherein the first energy level results from a second excited state of one of the at least two quantum wells, and wherein the second energy level results from a first excited state of one of the at least two quantum wells.

12. The quantum cascade source according to claim 1, comprising a fourth energy level, the fourth energy level having a lower energy value than that of the third energy level and configured so that an electron transition from a selected excited state energy level to the fourth energy level emits a photon of a selected wavelength.

13. The quantum cascade source according to claim 12, wherein the fourth energy level results from an excited state of one of the quantum wells.

14. The quantum cascade source according to claim 12, wherein the fourth energy level results from a ground state of one of the quantum wells.

15. The quantum cascade source according to claim 12, wherein the selected excited state energy level comprises the third energy level.

16. The quantum cascade source according to claim 12, wherein the photon emitted from the first to second energy level transition and the photon emitted from the selected excited state energy level to the fourth energy level transition have the same wavelength.

17. The quantum cascade source according to claim 12, wherein the photon emitted from the first to second energy level transition and the photon emitted from the selected excited state energy level to the fourth energy level transition have different wavelengths.

18. The quantum cascade source according to claim 12, wherein the electron transition between the selected excited state energy level and the fourth energy level comprises a vertical transition.

19. The quantum cascade source according to claim 12, wherein the selected excited state energy level and third energy level are configured so that an electron transition between the selected excited state energy level and the third energy level comprises a nonradiative transition.

20. The quantum cascade source according to claim 19, wherein the energy difference between the selected excited state energy level and the third energy level is sufficient to emit an optical phonon.

21. The quantum cascade source according to claim 19, wherein the energy difference between the selected excited state energy level and the third energy level corresponds to that of an optical phonon.

22. The quantum cascade source according to claim 1, wherein the quantum cascade source is a quantum cascade laser.

23. A quantum cascade source, comprising:
a plurality of repeat units each including an active region and an injector region having a plurality of layers, the repeat units stacked in contact with one another linearly along a direction perpendicular to the layers and disposed between first and second electrical contacts for applying an electrical bias across the stacked repeat units, each active region having at least two quantum wells that, in response to an applied electrical bias, support a first electron transition between a first pair of excited state energy levels to emit a photon of a first selected wavelength and support a second electron transition between a second pair of energy levels to emit a photon of a second selected wavelength, the lowest energy level of the first energy level pair and the highest energy level of the second energy level pair being separated in energy by an amount sufficient to emit an optical phonon.

24. The quantum cascade source according to claim 23, wherein the second energy level pair comprises two excited state energy levels.

25. The quantum cascade source according to claim 23, wherein the second energy level pair comprises an excited state energy level and a ground state energy level.

26. The quantum cascade source according to claim 23, wherein the lowest energy level of the first energy level pair and the highest energy level of the second energy level pair are separated in energy by at least that of two optical phonons.

27. The quantum cascade source according to claim 23, wherein the first and second wavelengths are equal.

28. The quantum cascade source according to claim 23, wherein the first and second wavelengths are different.

29. The quantum cascade source according to claim 23, wherein the first electron transition is a vertical transition.

30. The quantum cascade source according to claim 23, wherein the second electron transition is a vertical transition.

31. The quantum cascade source according to claim 23, wherein the at least two quantum wells comprises at least four quantum wells.

32. The quantum cascade source according to claim 23, comprising at least one energy level disposed between the lowest energy level of the first energy level pair and the highest energy level of the second energy level pair, the at least one energy level configured so that an electron transition between the lowest energy level of the first energy level pair and the at least one energy level comprises a nonradiative transition to empty the lowest energy level of the first energy level pair sufficiently quickly to promote a population inversion between the energy levels of the first energy level pair.

33. The quantum cascade source according to claim 32, wherein the at least one energy level and the lowest energy level of the first energy level pair are separated in energy by an amount sufficient to emit an optical phonon.

34. The quantum cascade source according to claim 32, wherein the at least one energy level comprises an excited state energy level.

35. The quantum cascade source according to claim 23, wherein the quantum cascade source is a quantum cascade laser.

36. A quantum cascade source, comprising:
a plurality of repeat units each including an active region and an injector region having a plurality of layers, the repeat units stacked in contact with one another linearly along a direction perpendicular to the layers and disposed between first and second electrical contacts for applying an electrical bias across the stacked repeat units, each active region having at least two quantum wells that, in response to an applied electrical bias, support only a single lasing electron transition between a pair of excited state energy levels to emit a photon of a selected wavelength and support a relatively lower energy level disposed below the lowest energy level of the energy level pair, the lowest energy level of the energy level pair and the relatively lower energy level configured so that an electron transition therebetween comprises a nonradiative transition to empty the lowest energy level of the energy level pair sufficiently quickly to promote a population inversion between the energy levels of the energy level pair.

37. The quantum cascade source according to claim 36, wherein the energy difference between the lowest energy level of the energy level pair and the relatively lower energy level is sufficient to emit an optical phonon.

38. The quantum cascade source according to claim 37, wherein the energy difference between the lowest energy level of the energy level pair and the relatively lower energy level corresponds to that of an optical phonon.

39. The quantum cascade source according to claim 36, wherein the lasing transition is a vertical transition.

40. The quantum cascade source according to claim 36, wherein the highest energy level of the energy level pair results from a second excited state of one of the at least two quantum wells, and wherein the lowest energy level of the energy level pair results from a first excited state of one of the at least two quantum wells.

41. The quantum cascade source according to claim 36, wherein the quantum cascade source is a quantum cascade laser.
